(19) United States
(12) Patent Application Publication
(10) Pub. No.: US 2024/0393598 A1
(43) Pub. Date: Nov. 28, 2024

(54) OPTICAL ENGINE, DISPLAY STRUCTURE, DISPLAY DEVICE, AND VEHICLE

(71) Applicant: DISPELIX OY, Espoo (FI)

(72) Inventor: Riku RIKKOLA, Tampere (FI)

(73) Assignee: DISPELIX OY, Espoo (FI)

(21) Appl. No.: 18/693,478

(22) PCT Filed: Sep. 19, 2022
(86) PCT No.: PCT/FI2022/050623

§ 371 Date: Mar. 19, 2024

(30) Foreign Application Priority Data
Sep. 22, 2021 (FI) 20215991

(51) Int. Cl. G02B 27/01; H01L 33/00; H01L 33/30

(52) U.S. Cl. CPC G02B 27/0172; H01L 33/0045; G02B 2027/0178; H01L 33/30

(57) ABSTRACT

This disclosure relates to an optical engine, a display structure, a display device, and a vehicle. The optical engine comprises an illumination arrangement comprising a first light source configured to emit first light having a first peak wavelength and a superluminescent light source configured to emit second light having a second peak wavelength different from the first peak wavelength.

### FIELD OF TECHNOLOGY

This disclosure concerns display devices. In particular, this disclosure concerns multicolor optical engines, waveguide-based display structures comprising such optical engines, display devices comprising such display structures, and vehicles comprising such display devices.

### BACKGROUND

In modern display devices, laser light sources are commonly used due to their higher image sharpness and lowered energy consumption as well as the smaller form factors achievable with such sources. The latter two benefits, i.e., lowered energy consumption and smaller form factor, are especially beneficial for portable display devices, such as head-mounted display devices.

The sizes and masses of portable display devices may be further decreased by utilization of waveguide-based structures for guiding light from the optical engines of such display devices towards the users' eye(s). Additionally, when utilizing such waveguide-based structures, yet further reductions in display device sizes and masses may be achievable by using diffractive incoupling structures for coupling light into waveguides.

Since the images produced by typical optical engines are relatively small, exit-pupil-expansion methods are commonly used to increase the sizes of output images in conventional portable waveguide-based display devices.

However, due to chromatic dispersion in diffractive incoupling structures and the narrowness of light beams emitted by typical laser light sources, it may be challenging to couple all light emitted by a conventional laser-based multicolor optical engine into a waveguide via a diffractive in-coupling structure without excessively impeding image quality.

In light of this, it may be desirable to develop new solutions related to display devices.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

According to a first aspect, an optical engine for a display device is provided. The optical engine comprises an illumination arrangement comprising a first light source configured to emit first light having a first peak wavelength and a superluminescent light source configured to emit second light having a second peak wavelength different from the first peak wavelength.

According to a second aspect, a display structure is provided. The display structure comprises a waveguide, an in-coupling structure, and an optical engine in accordance with the first aspect configured to direct light via the in-coupling structure into the waveguide for propagation in the waveguide by total internal reflection.

According to a third aspect, a display device comprising a display structure in accordance with the third aspect is provided.

According to a fourth aspect, a vehicle comprising a display device in accordance with the third aspect is provided.

### BRIEF DESCRIPTION OF THE DRAWINGS

The present disclosure will be better understood from the following detailed description read in light of the accompanying drawings, wherein:

FIG. 1 shows an optical engine,

FIG. 2 depicts a normalized emission spectrum of an illumination arrangement,

FIG. 3 illustrates a cross-sectional view of a superluminescent diode,

FIG. 4 shows a display structure,

FIG. 5 depicts another display structure,

FIG. 6 illustrates a waveguide,

FIG. 7 shows a display device, and

FIG. 8 depicts a vehicle.

Unless specifically stated to the contrary, any drawing of the aforementioned drawings may be not drawn to scale such that any element in said drawing may be drawn with inaccurate proportions with respect to other elements in said drawing in order to emphasize certain structural aspects of the embodiment of said drawing.

Moreover, corresponding elements in the embodiments of any two drawings of the aforementioned drawings may be disproportionate to each other in said two drawings in order to emphasize certain structural aspects of the embodiments of said two drawings.

### DETAILED DESCRIPTION

Concerning optical engines, display structures, and display devices discussed in this detailed description, the following shall be noted.

In this specification, a “display device” may refer to an operable output device, e.g., electronic device, for visual presentation of images and/or data. A display device may generally comprise at least one optical engine. A display device may optionally further comprise any part(s) or element(s) necessary or beneficial for visual presentation of images and/or data, for example, a power unit; a combiner optics unit, such as a waveguide-based combiner optics unit; an eye tracking unit; a head tracking unit; a gesture sensing unit; and/or a depth mapping unit. A display device may or may not be a portable display device, for example, head-mounted display device, and/or a see-through display device, such as a head-up display device.

Herein, a “unit” may refer to an element suitable for or configured to perform at least one specific process. A unit may generally comprise one or more parts, and each of the one or more parts may be classified as belonging to an arrangement of said unit. An “arrangement” of a unit configured to perform a process may refer to a set of one or more parts of said unit suitable for or configured to perform at least one specific subprocess of said process. As such, a “unit comprising an arrangement” may refer to said unit comprising part(s) belonging to said arrangement. Generally, an arrangement may comprise any elements(s), for example, mechanical, electrical, and/or optical elements, necessary and/or beneficial for performing its specific subprocess.

Further, an “optical engine”, or “display engine”, may refer to a unit for or of a display device suitable for or configured to generate visual content for a user of the display device. Additionally or alternatively, an “optical engine” may refer to a unit for or of a display device suitable for or configured to form an image, for example, in the angular spectrum, to be passed on to an in-coupling structure. An optical engine may comprise an illumination arrangement comprising at least one light source and, optionally, any part(s) or element(s) necessary or beneficial for controlling said at least one light source. An optical engine may optionally further comprise any part(s) or element(s) necessary or beneficial for generation of visual content, for example, a graphics processing unit (GPU); a light combiner arrangement; light steering optics, such as a light 20 scanner arrangement; and/or a light relay arrangement.

Throughout this disclosure, a “display structure” may refer to at least part of a display device. As such, a display structure may or may not form an operable display device.

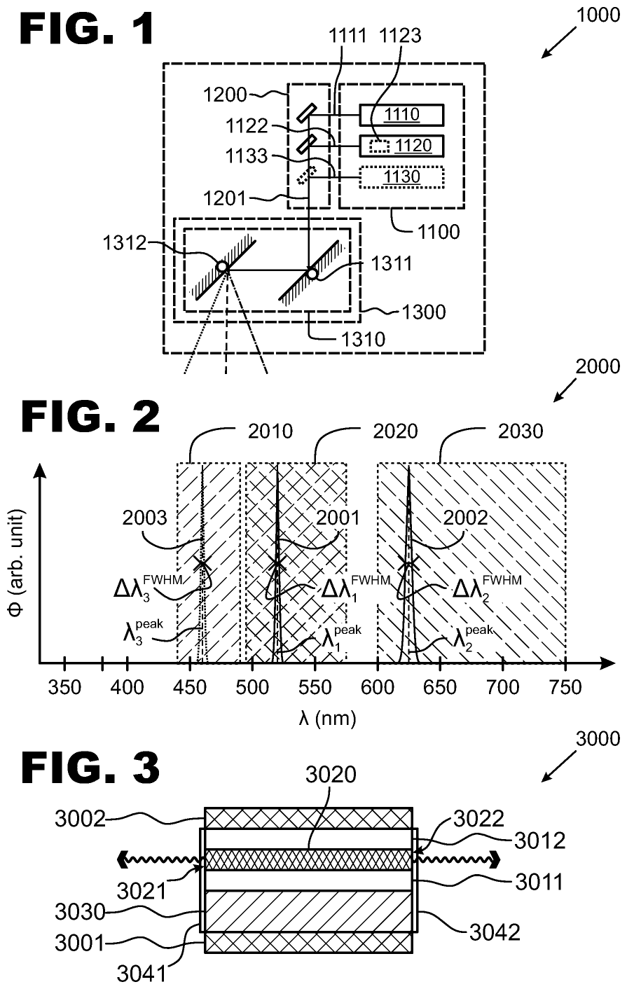

FIG. 1 schematically depicts an optical engine 1000 according to an embodiment. The optical engine 1000 comprises an illumination arrangement 1100 comprising a first light source 1110 configured to emit first light 1111 having a first peak wavelength peak) and a superluminescent light source 1120 configured to emit second light 1122 having a second peak wavelength (λ₂^{peak}) different from λ₁^{fear}. Generally, an illumination arrangement of an optical engine for a waveguide-based display device comprising a superluminescent light source may facilitate reducing spatial intensity variations caused by optical interference in an image coupled out from a waveguide. Additionally or alternatively, an illumination arrangement of an optical engine comprising a first light source configured to emit first light having a first peak wavelength and a superluminescent light source configured to emit second light having a second peak wavelength different from the first peak wavelength may facilitate coupling light emitted by the optical engine into a waveguide of a display device via a diffractive in-coupling structure without excessively impeding image quality of the display device.

In this disclosure, a “waveguide” may refer to an optical waveguide. Additionally or alternatively, a waveguide may refer to a two-dimensional waveguide, wherein light may be confined along a thickness direction of said waveguide.

Throughout this specification, an “in-coupling structure” may refer to a structure suitable for or configured to couple light into a waveguide for propagation in the waveguide by total internal reflection. Generally, an in-coupling structure may comprise, for example, one or more diffractive optical elements, such as diffraction gratings; one or more reflective optical elements, such as mirrors; and/or one or more refractive optical elements, such as prisms.

Herein, a “diffractive optical element”, may refer to an optical element the operation of which is based on diffraction of light. Generally, a diffractive optical element may comprise structural features with at least one dimension of the order of the wavelengths of visible light, for example, at least one dimension less than one micrometer. Typical examples of diffractive optical elements comprise diffraction gratings, e.g., one- and two-dimensional diffraction gratings, which may be implemented as single-region diffraction gratings or as multi-region diffraction gratings. Diffraction gratings may generally be implemented, at least, as surface relief diffraction gratings or volume holographic diffraction gratings, and they may be configured to function as transmission- and/or reflection-type diffraction gratings.

Consequently, a “diffractive in-coupling structure” may refer to an in-coupling structure comprising a diffractive optical element.

In the embodiment of FIG. 1, the first light source 1110 is implemented as a laser light source. In other embodiments, a first light source may be implemented in any suitable manner, for example, as a laser light source, a superluminescent light source, or a light-emitting diode source.

As indicated in FIG. 1 using dotted lines, the superluminescent light source 1120 may comprise a superluminescent diode 1123. Generally, a superluminescent light source comprising a superluminescent diode may facilitate forming an illumination arrangement of an optical engine with a reduced form factor. In other embodiments, a superluminescent light source may comprise any suitable type(s) of component(s) for achieving superluminescence or amplified spontaneous emission, for example, superluminescent diode(s) and/or dye-based light-emitting device(s).

As further illustrated in FIG. 1 using dotted lines, the illumination arrangement 1100 may comprise a further light source 1130 configured to emit third light 1133 having a third peak wavelength (λ₃^{peak}) different from each of λ₁^{peak} and λ₂^{peak}. Generally, an illumination arrangement of an optical engine comprising such further light source may enable using said optical engine for additive color mixing with three colors, for example, for RGB image formation. In other embodiments, an illumination arrangement may or may not comprise one or more further light sources in addition to a first light source and a superluminescent light source. In such other embodiments, at least one, for example, each, of said one or more further light sources may or may not be configured to emit light at peak wavelength(s) different from a first peak wavelength and/or a second peak wavelength. In some embodiments, more than one light sources may be configured to emit light at a single, i.e., the same, wavelength.

In the embodiment of FIG. 1, the further light source 1130 may be implemented as a further laser light source. Generally, a further light source being implemented as a further laser light source or as a further superluminescent light source may facilitate reducing the form factor and/or the energy consumption of an optical engine suitable for additive color mixing with three colors. In other embodiments, wherein an illumination arrangement comprises a further light source configured to emit third light having a third peak wavelength different from each of a first peak wavelength and a second peak wavelength, the further light source may be implemented in any suitable manner, for example, as a further laser light source or as a further superluminescent light source.

In the embodiment of FIG. 1, the optical engine 1000 comprises a light combiner arrangement 1200 for combining at least first light 1111 emitted by the first light source 1110 and second light 1122 emitted by the superluminescent light source 1120 to form combined light 1201. In other embodiments, an optical engine may or may not comprise such light combiner arrangement.

In case the illumination arrangement 1100 also comprises the further light source 1130, the light combiner arrangement 1200 may be configured to combine first light 1111 emitted by the first light source 1110, second light 1122 emitted by the superluminescent light source 1120, and third light 1133 emitted by the further light source 1130 to form the combined light 1201. In other embodiments, wherein an illumination arrangement comprises at least one further light source and a light combiner arrangement, the light combiner arrangement may be suitable for or configured to combine light emitted by any or all individual light sources of the illumination arrangement.

The optical engine 1000 of the embodiment of FIG. 1 further comprises a light scanner arrangement 1300 for deflecting light generated by the illumination arrangement 1100. The optical engine 1000 is configured to receive combined light 1201 formed by the light combiner arrangement 1200. Generally, an optical engine of a display device comprising such light scanner arrangement may enable reducing a form factor of the display device. In other embodiments, an optical engine may be implemented in any suitable manner. As such, an optical engine may or may not comprise a light scanner arrangement for deflecting light generated by an illumination arrangement. In some embodiments, an optical engine may comprise a non-scanning micromirror device, such as a micromirror device comprising an array of micromirror actuators; and/or a Liquid Crystal on Silicon (LCoS) device in addition or as an alternative to a light scanner arrangement.

The light scanner arrangement 1300 of the embodiment of FIG. 1 comprises a micromirror scanner 1310. Generally, micromirror scanners may provide reduced mass and/or power consumption. Additionally or alternatively, micromirror scanners may provide reduced need for maintenance and/or increased reliability under demanding operation conditions. In other embodiments, wherein an optical engine comprises a light scanner arrangement for deflecting light generated by an illumination arrangement, the light scanner arrangement may comprise any suitable type(s) of component(s), for example, micromirror scanner(s), fiber scanner(s), integrated electro-optic scanner(s), acousto-optical modulator(s), phased-array beam steerer(s), and/or surface acoustic wave (SAW) scanner(s).

Herein, a “micromirror scanner”, or “microscanner” or “scanning micromirror”, may refer to a micromirror-based actuator for modulation of light. Additionally of alternatively, a micromirror scanner may refer to a microoptoelectromechanical system (MOEMS) for deflecting light generated by an illumination arrangement. Generally, a micromirror scanner may or may not comprise a digital micromirror device (DMD). In a micromirror scanner, modulation of light may be caused by translatory and/or rotation movement of a mirror, e.g., a micromirror, on one or more axes.

In the embodiment of FIG. 1, the micromirror scanner 1310 comprises a first deflection mirror 1311 and a second deflection mirror 1312. Each of the first deflection mirror 1311 and the second deflection mirror 1312 is a one-dimensionally scanning micromirror. Consequently, the micromirror scanner 1310 of the embodiment of FIG. 1 is implemented as a dual one-dimensional micromirror scanner. In other embodiments, wherein a light scanner arrangement comprises a micromirror scanner, the micromirror scanner may be implemented in any suitable manner, for example, as a one-dimensional micromirror scanner, a dual one-dimensional micromirror scanner, or a two-dimensional micromirror scanner.

The optical engine 1000 of the embodiment of FIG. 1 may be configured for non-pupil imaging. In other embodiments, an optical engine may or may not be configured for non-pupil imaging. For example, in some embodiments, an optical engine may be configured for pupil imaging, comprising a light relay arrangement configured to form an intermediate image and an output pupil of the optical engine.

FIG. 2 depicts a normalized emission spectrum 2000 of an illumination arrangement of an optical engine according to an embodiment. The optical engine of the embodiment of FIG. 2 or any part(s) thereof may be in accordance with any of the embodiments disclosed with reference to or in conjunction with FIG. 1.

The emission spectrum 2000 of the embodiment of FIG. 2 comprises a first optical spectrum 2001 of first light emitted by a first light source, which may be implemented, for example, as a laser light source, and a second optical spectrum 2002 emitted by a superluminescent light source. The first light has a first peak wavelength (λ₁^{peak}) and the second light has a second peak wavelength (λ₂^{peak}) different from λ₁^{peak}.

In the embodiment of FIG. 2, λ₂^{peak} is higher than λ₁^{peak}. Typically, a diffractive in-coupling structure of a waveguide of a display structure is configured to couple light into its first diffraction order. Under such conditions, light of longer wavelengths propagates in a waveguide with longer bounce periods. Generally, λ₂^{peak} being higher than λ₁^{peak} may facilitate coupling light emitted by the optical engine into a waveguide of a display device via a diffractive in-coupling structure without excessively impeding image quality of the display device especially at such longer wavelengths. In other embodiments, a second peak wavelength may or may not be higher than a first peak wavelength. In some embodiments, a second peak wavelength may be lower than a first peak wavelength.

In the embodiment of FIG. 2, the first optical spectrum 2001 has a full-width-half-maximum (FWHM) linewidth (Δλ₁^{FWHM}), and the second optical spectrum 2002 has a FWHM linewidth (Δλ₂^{FWHM}) greater than Δλ₁^{FWHM}. In other embodiments, a FWHM linewidth of a second optical spectrum may or may not be greater than a FWHM linewidth of a first optical spectrum.

In the embodiment of FIG. 2, Δλ₁^{FWHM} is less than 2 nanometers (nm). In other embodiments, a first optical spectrum may have any suitable linewidth, for example, a linewidth less than 2 nm, or than 4 nm, or than 5 nm. In the embodiment of FIG. 2, Δλ₁^{FWHM} is greater than 2 nm. Generally, a higher linewidth of a second optical spectrum of second light may increase density of sub-pupils at an out-coupling structure of a waveguide, which, in turn, may facilitate coupling light emitted by an optical engine into the waveguide via a diffractive incoupling structure without excessively impeding image quality. Additionally or alternatively, a higher linewidth of a second optical spectrum of second light may facilitate reducing spatial intensity variations caused by optical interference in an image coupled out from a waveguide.

In the embodiment of FIG. 2, Δλ₂^{FWHM} is less than 10 nm. Generally, a lower linewidth of a second optical spectrum of second light may reduce dispersion-related image defects. In other embodiments, a second optical spectrum of second light may have any suitable linewidth, for example, a linewidth greater than or equal to 2 nm, or to 3 nm, or to 4 nm, or to 5 nm and/or less than or equal to 50 nm, or to 40 nm, or to 30 nm, or to 20 nm, or to 10 nm.

In the embodiment of FIG. 2, the illumination arrangement may comprise a further light source configured to emit third light having a third peak wavelength (Aga different from each of λ₁^{peak} and λ₂^{peak}. Consequently, as depicted in FIG. 2 using dotted lines, the emission spectrum 2000 may comprise a third optical spectrum 2003 of such third light.

In the embodiment of FIG. 2, λ₃^{peak} may be lower than each peak of λ₁^{peak} and λ₂^{peak}. In other embodiments, a third peak wavelength of third light emitted by a further light source may or may not be lower than first light emitted by a first light source and/or second light emitted by a superluminescent light source.

The λ₁^{peak}, λ₂^{peak}, and λ₃^{peak} of the embodiment of FIG. 2 lie in a green wavelength range 2020, a red wavelength range 2030, and a blue wavelength range 2010, respectively. In other embodiments, any of a first peak wavelength, a second peak wavelength, and a third peak wavelength may or may not lie in any of a blue wavelength range, a green wavelength range, and a red wavelength range. For example, a second peak wavelength may or may not lie in a blue wavelength range, a green wavelength range, or a red wavelength range.

Throughout this specification, a “blue wavelength range” may refer to a wavelength range extending from 440 nm to 490 nm, or from 450 nm to 485 nm.

In this specification, a “green wavelength range” may refer to a wavelength range extending from 495 nm to 575 nm, or from 500 nm to 565 nm.

Further, a “red wavelength range” may refer to a wavelength range extending from 600 nm to 750 nm, or from 610 nm to 700 nm, or from 620 nm to 650 nm, or from 625 nm to 640 nm.

In the embodiment of FIG. 2, the third optical spectrum 2003 may have a FWHM linewidth (Δλ₃^{FWHM}) less than 2 nm. In other embodiments, a third optical spectrum may have any suitable linewidth, for example, a linewidth less than 2 nm, or than 4 nm, or than 5 nm. In some embodiments, a further light source may be implemented as a further superluminescent light source. In such embodiments, a third optical spectrum of third light emitted by the further light source may have a linewidth, for example, greater than or equal to 2 nm, or to 3 nm, or to 4 nm, or to 5 nm and/or less than or equal to 50 nm, or to 40 nm, or to 30 nm, or to 20 nm, or to 10 nm.

FIG. 3 schematically depicts a cross-sectional view of a superluminescent diode 3000 of a superluminescent light source or a further superluminescent light source of an illumination arrangement of an optical engine according to an embodiment. The optical engine of the embodiment of FIG. 3 or any part(s) thereof may be in accordance with any of the embodiments disclosed with reference to or in conjunction with any of FIGS. 1 and 2.

In the embodiment of FIG. 3, the superluminescent diode 3000 comprises a substrate 3030, a first cladding layer 3011 arranged on the substrate 3030, an active layer 3020 on the first cladding layer 3011, and a second cladding layer 3012 on the active layer 3020. The active layer 3020 is arranged between the first cladding layer 3011 and the second cladding layer 3012.

The superluminescent diode 3000 of the embodiment of FIG. 3 further comprises a first electrode 3001 connected to the substrate 3030 and a second electrode 3002 connected with the second cladding layer 3012 for applying an operating voltage over the first cladding layer 3011, the active layer 3020, and the first cladding layer 3011 during operation. In other embodiments, wherein a superluminescent light source comprises a superluminescent diode, the superluminescent diode may have any suitable type of structure.

In the embodiment of FIG. 3, the active layer 3020 comprises a first end facet 3021 and a second end facet 3022, and the superluminescent diode 3000 comprises a first antireflection coating 3041 on the first end facet 3021 and a second antireflection coating 3042 on the second end facet 3022 for limiting optical feedback in the active layer 3020 such that lasing is inhibited. In other embodiments, a superluminescent diode may be configured to operate below a lasing threshold thereof by any suitable means. For example, in some embodiments, an active layer of a superluminescent diode may be provided with tilted and anti-reflection coated end facets.

In the embodiment of FIG. 3, the active layer 3020 comprises aluminum gallium indium phosphide, AlGaInP. Generally, an active layer of a superluminescent diode comprising AlGaInP may enable emission in a red wavelength range with reduced energy consumption, especially at shorter wavelengths. In other embodiments, an active layer of a superluminescent diode may or may not comprise AlGaInP.

In particular, the active layer 3020 of the embodiment of FIG. 3 may be implemented as a AlGaInP multi-quantumwell active layer. In such case, the peak wavelength of light emitted by the superluminescent diode 3000 may be tunable by adjusting quantum well thicknesses in the active layer 3020. In other embodiments, an active layer may or may not be implemented as a multi-quantumwell active layer, e.g., as a AlGaInP multi-quantumwell active layer.

It is to be understood that the embodiments of the first aspect described above may be used in combination with each other. Several of the embodiments may be combined together to form a further embodiment.

Above, mainly aspects related to optical engines are discussed. In the following, more emphasis will lie on aspects related to display structures and display devices. What is said above about the ways of implementation, definitions, details, and advantages related to the optical engine aspect apply, mutatis mutandis, to the aspects discussed below. The same applies vice versa.

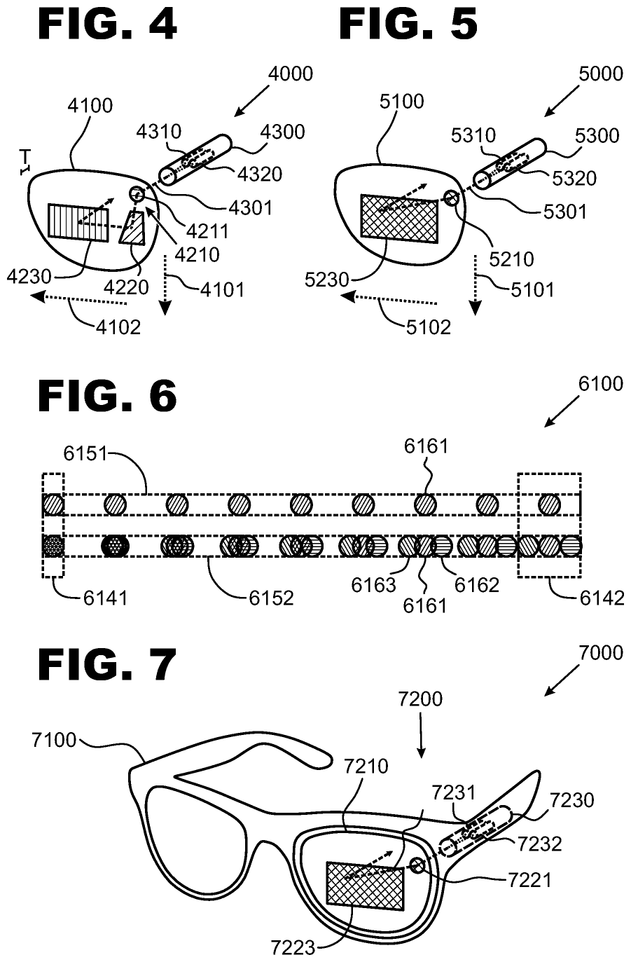

FIG. 4 depicts a display structure 4000 according to an embodiment. The embodiment of FIG. 4 may be in accordance with any of the embodiments disclosed with reference to or in conjunction with any of FIGS. 1 to 3.

Additionally or alternatively, although not explicitly shown in FIG. 4, the embodiment of FIG. 4 or any part thereof may generally comprise any features and/or elements of any of the embodiments of FIGS. 1 to 3 which are omitted from FIG. 4.

In the embodiment of FIG. 4, the display structure 4000 comprises a waveguide 4100 and an in-coupling structure 4210. The display structure 4000 of the embodiment of FIG. 4 further comprises an optical engine 4300 in accordance with the first aspect of this specification. The optical engine 4300 is configured to direct light 4301 via the in-coupling structure 4210 into the waveguide 4100 for propagation in the waveguide 4100 by total internal reflection.

In the embodiment of FIG. 4, the display structure 4000 is configured to perform exit pupil expansion by pupil replication along at least a first replication direction 4101. In other embodiments, a display structure may or may not be configured is such manner.

Herein, “exit pupil expansion” may refer to a process of distributing light within a waveguide in a controlled manner so as to expand the portion of said waveguide wherefrom out-coupling of light occurs.

Further, “pupil replication” may refer to an exit pupil expansion process, wherein a plurality of exit sub-pupils are formed in an imaging system. It has been found that, in waveguide-based multicolor imaging systems relying on pupil replication for exit pupil expansion, individual exit sub-pupils are preferably arranged in an overlapping manner for all angles and all colors of light at the portion of said waveguide wherefrom outcoupling of light occurs. Such arrangement of exit subpupils may enable avoiding the formation of spatial intensity variations in an out-coupled image, which are typically perceived as dark fringes.

Throughout this specification, a “first replication direction” may refer to a direction along which a waveguide is configured to perform pupil replication. Further, a waveguide being configured to perform “pupil replication along at least a first replication direction” may refer to said waveguide being configured to perform one-dimensional, for example, horizontal or vertical, pupil replication or two-dimensional, for example, horizontal and vertical, pupil replication.

The in-coupling structure 4210 of the embodiment of FIG. 4 is implemented as a diffractive in-coupling structure. As such, the in-coupling structure 4210 comprises an in-coupling grating 4211. In other embodiments, an in-coupling structure may be implemented in any suitable manner, for example, as a diffractive incoupling structure.

The optical engine 4300 of the embodiment of FIG. 4 comprises a first light source 4310 and a superluminescent light source 4320. Additionally, although not depicted in FIG. 4, the optical engine 4300 may further comprise one or more further light sources in addition to the first light source 4310 and the superluminescent light source 4320. Such one or more further light sources may be implemented in any suitable manner, for example, as one or more laser light sources, and/or one or more further superluminescent light sources, and/or one or more light-emitting diode sources.

In the embodiment of FIG. 4, the display structure 4000 comprises an intermediate pupil expansion structure 4220 configured to receive light 4301 from the incoupling structure 4210 and an out-coupling structure 4230 configured to receive light 4301 from the intermediate pupil expansion structure 4220. In other embodiments, a display structure may or may not comprise such intermediate pupil expansion structure and such out-coupling structure.

In this disclosure, an “out-coupling structure” may refer to a structure configured to couple light out of a waveguide. Generally, an out-coupling structure may comprise, for example, one or more diffractive optical elements, such as diffraction gratings; one or more reflective optical elements, such as mirrors; and/or one or more refractive optical elements, such as prisms.

The display structure 4000 of the embodiment of FIG. 4 is configured to perform exit pupil expansion by pupil replication along the first replication direction 4101 using the intermediate pupil expansion structure 4220 and along a second replication direction 4102 perpendicular to the first replication direction 4101 using the using the out-coupling structure 4230. In other embodiments, a display structure may or may not be configured in such manner.

In the embodiment of FIG. 4, each of the in-coupling structure 4210, the intermediate pupil expansion structure 4220, and the out-coupling structure 4230 may comprise one or more one-dimensional diffraction gratings. In other embodiments, any or all of an in-coupling structure, an intermediate pupil expansion structure, and an out-coupling structure may or may not comprise one or more one-dimensional diffraction gratings.

The waveguide 4100 of the embodiment of FIG. 4 may have a thickness (T) of approximately 0.3 millimeters (mm). Generally, a lower thickness of a waveguide may increase a density of sub-pupils at an out-coupling structure of a waveguide, which may, in turn facilitate avoiding the formation of spatial intensity variations in an outcoupled image, whereas a higher thickness of a waveguide may facilitate fabrication of a waveguide-based display device. In other embodiments, a waveguide may have any suitable thickness, for example a thickness greater than or equal to 0.25 mm, or to 0.27 mm, or to 0.3 mm and/or less than or equal to 5 mm, or to 2 mm, or to 1 mm.

FIG. 5 depicts a display structure 5000 according to an embodiment. The embodiment of FIG. 5 may be in accordance with any of the embodiments disclosed with reference to or in conjunction with any of FIGS. 1 to 4. Additionally or alternatively, although not explicitly shown in FIG. 5, the embodiment of FIG. 5 or any part thereof may generally comprise any features and/or elements of any of the embodiments of FIGS. 1 to 4 which are omitted from FIG. 5.

In particular, similarly to the display structure 4000 of the embodiment of FIG. 4, the display structure 5000 of the embodiment of FIG. 5 also comprises a waveguide 5100 as well as an optical engine 5300 comprising a first light source 5310 and a superluminescent light source 5320. Additionally, the waveguide 5100 comprises a diffractive in-coupling structure 5210 configured to couple light 5301 originating from the optical engine 5300 into the waveguide 5100.

However, contrary to the embodiment of FIG. 4, the waveguide 5100 of the embodiment of FIG. 5 comprises an outcoupling structure 5230 configured to receive light 5301 directly from the in-coupling structure 5210.

The display structure 5000 of the embodiment of FIG. 5 is configured to perform exit pupil expansion by pupil replication along both a first replication direction 5101 and a second replication direction 5102 using the out-coupling structure 5230. In other embodiments, a display structure may or may not be configured in such manner.

In the embodiment of FIG. 5, the in-coupling structure 5210 and the out-coupling structure 5230 may comprise one or more two-dimensional diffraction gratings. In other embodiments, any or all of an in-coupling structure, an intermediate pupil expansion structure, and an out-coupling structure may or may not comprise one or more two-dimensional diffraction gratings.

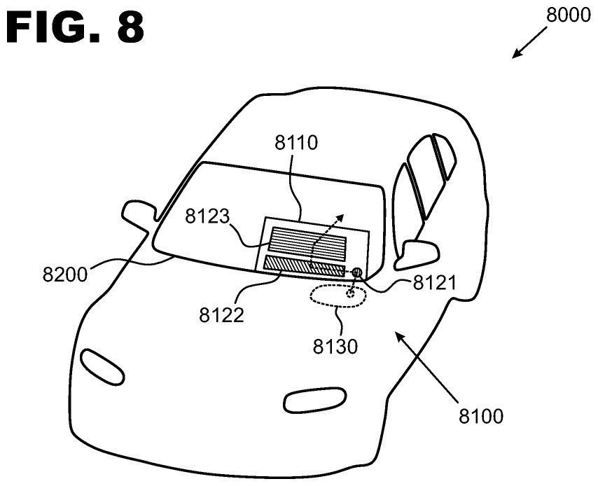

FIG. 6 depicts a schematic view of a waveguide 6100. In FIG. 6, the plane of the drawing extends parallel to a face of the waveguide 6100.

In this disclosure, a “face” of a waveguide may refer to a part of a surface of said waveguide viewable from or facing a certain viewing direction. Additionally or alternatively, faces of a waveguide may refer to surfaces suitable for or configured to confine light in said waveguide by total internal reflection.

In FIG. 6, a first diffractive structure 6141 is configured to direct light towards a second diffractive structure 6142, the light propagating in the waveguide 6100 by total internal reflection. The first diffractive structure 6141 may be, for example, an in-coupling structure, and the second diffractive structure 6142 may be, for example, an intermediate pupil expansion structure or an out-coupling structure.

In FIG. 6, a first propagation path 6151 and a second propagation path 6152 are depicted, first light emitted by a first light source propagating along the first propagation path 6151 and second light emitted by a superluminescent light source propagating along the second propagation path 6152.

The first light depicted in FIG. 6 has a first peak wavelength and a first optical spectrum. The second light has a second optical spectrum broader than the first optical spectrum. However, contrary to, for example, the first light 1111 and second light 1122 of the embodiment of FIG. 1, the second light depicted in FIG. 6 has the same first peak wavelength as the first light depicted in FIG. 6.

On the one hand, to highlight the lower breadth of the first optical spectrum, the first light is depicted in FIG. 6 as being monochromatic such that for any specific incidence angle of the first light the first light reflects from the face of the waveguide 6100 at equally spaced peak wavelength sub-pupils 6161.

On the other hand, to highlight the increased breadth of the second optical spectrum, the second light is depicted in FIG. 6 such that for any specific incidence angle of the first light the second light reflects from the face of the waveguide 6100 not merely at the peak wavelength sub-pupils 6161 but also at equally spaced secondary wavelength sub-pupils 6162 and at equally spaced tertiary wavelength sub-pupil 6163.

The secondary wavelength sub-pupils 6162 exhibit an inter-sub-pupil distance higher than that of the peak wavelength sub-pupils 6161, whereas the tertiary wavelength sub-pupil 6163 exhibit an inter-sub-pupil distance lower than that of the peak wavelength sub-pupils 6161. Due to this variation of inter-sub-pupil distances at different wavelengths, the second light exhibits a sub-pupil density higher than that of the first light at the second diffractive structure 6142. Such higher sub-pupil density achievable with superluminescent light sources may facilitate avoiding the formation of spatial intensity variations in an image coupled out from a waveguide. In particular, such higher sub-pupil density may reduce the so-called “pupil banding” effect perceivable by an observer moving relative to such image.

FIG. 7 depicts a display device 7000 according to an embodiment. The embodiment of FIG. 7 may be in accordance with any of the embodiments disclosed with reference to or in conjunction with any of FIGS. 1 to 5. Additionally or alternatively, although not explicitly shown in FIG. 7, the embodiment of FIG. 7 or any part thereof may generally comprise any features and/or elements of any of the embodiments of FIGS. 1 to 5.

In the embodiment of FIG. 7, the display device 7000 is implemented as a see-through head-mounted display device, more specifically, as spectacles comprising a see-through display. In other embodiments, a display device may be implemented in any suitable manner, for example, as a see-through and/or as a head-mounted display device.

Throughout this specification, a “see-through display device” or “transparent display device” may refer to a display device allowing its user to see the images and/or data shown on the display device as well as to see through the display device.

Further, a “head-mounted display device” may refer to a display device configured to be worn on the head, as part of a piece of headgear, and/or on or over the eyes.

In the embodiment of FIG. 7, the display device 7000 comprises a frame 7100 and a display structure 7200 according to the second aspect supported by the frame 7100.

The display structure 7200 comprises a waveguide 7210, a diffractive in-coupling structure 7221, a diffractive out-coupling structure 7223 configured to receive light from the in-coupling structure 7221, and an optical engine 7230 comprising a first light source 7231 and a superluminescent light source 7232 and configured to direct light via the in-coupling structure 7221 into the waveguide 7210 for propagation in the waveguide 7210 by total internal reflection.

FIG. 8 schematically depicts a vehicle 8000 according to an embodiment. In the embodiment of FIG. 8, the vehicle 8000 is implemented as a car. In other embodiments, a vehicle may or may not be implemented as a car. For example, in some embodiments, a vehicle may be implemented as a motor vehicle, such as a car, a truck, or a bus; a railed vehicle, such as a train or a tram; a watercraft, such as a ship or a boat; an aircraft, such as an airplane, helicopter; or a spacecraft.

In the embodiment of FIG. 8, the vehicle 8000 comprises a display device 8100 in accordance with the third aspect. Even if not explicitly shown in FIG. 8, the embodiment of FIG. 8 or any part thereof may generally comprise any features and/or elements of any of the embodiments of FIGS. 1 to 5.

In the embodiment of FIG. 8, the display device 8100 comprises a waveguide 8110, an in-coupling structure 8121, an intermediate pupil expansion structure 8122, an out-coupling structure 8123, and an optical engine 8130. In other embodiments, a vehicle may comprise any suitable type(s) of display device(s) in accordance with the third aspect.

The display device 8100 of the embodiment of FIG. 8 is implemented as a head-up display device. In other embodiments, a display device may or may not be implemented as a head-up display device.

Herein, a “head-up display device” may refer to a see-through display device configured to present images and/or data to a steerer, e.g., a driver or a pilot, of a vehicle without requiring said steerer to look away from usual viewpoints thereof.

In the embodiment of FIG. 8, the display device 8100 further comprises a laminated window 8200, and the waveguide 8110 extends within the window 8200. In other embodiments, one or more waveguides may be arranged in any suitable manner(s). In some embodiments, a waveguide may extend within a laminated window, such as a windshield. In some embodiments, a vehicle may comprise a waveguide at a distance from a window.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described above may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

REFERENCE SIGNS

| λ₁^{peak} | first peak wavelength of the first light |
|---|---|
| λ₂^{peak} | second peak wavelength of the second light |
| λ₃peak | third peak wavelength of the third light |
| Δλ₁^{FWHM} | linewidth of the first optical spectrum of the |
| | first light |
| Δλ₂^{FWHM} | linewidth of the second optical spectrum of the |
| | second light |
| Δλ₃^{FWHM} | linewidth of the second optical spectrum of the |
| | third light |
| T | thickness of the waveguide |
| 1000 | optical engine |
| 1100 | illumination arrangement |
| 1110 | first light source |
| 1111 | first light |
| 1120 | superluminescent light source |
| 1122 | second light |
| 1123 | superluminescent diode |
| 1130 | further light source |
| 1133 | third light |
| 1200 | light combiner |
| 1201 | combined light |
| 1300 | light scanner arrangement |
| 1310 | micromirror scanner |
| 1311 | first deflection mirror |
| 1312 | second deflection mirror |
| 2000 | emission spectrum |
| 2001 | first optical spectrum |
| 2002 | second optical spectrum |
| 2003 | third optical spectrum |
| 2010 | blue wavelength range |
| 2020 | green wavelength range |
| 2030 | red wavelength range |
| 3000 | superluminescent diode |
| 3001 | first electrode |
| 3002 | second electrode |
| 3011 | first cladding layer |
| 3012 | second cladding layer |
| 3020 | active layer |
| 3021 | first end facet |
| 3022 | second end facet |
| 3030 | substrate |
| 3041 | first antireflection |
| 3042 | second antireflection coating |
| 4000 | display structure |
| 4100 | waveguide |
| 4101 | first replication direction |
| 4102 | second replication direction |
| 4210 | in-coupling structure |
| 4211 | in-coupling grating |
| 4220 | intermediate pupil expansion structure |
| 4230 | out-coupling structure |
| 4300 | optical engine |
| 4301 | light |
| 4310 | first light source |
| 4320 | superluminescent light source |
| 5000 | display structure |
| 5101 | first replication direction |
| 5102 | second replication direction |
| 5210 | in-coupling structure |
| 5230 | out-coupling structure |
| 5300 | optical engine |
| 5301 | light |
| 5310 | first light source |
| 5320 | superluminescent light source |
| 6100 | waveguide |
| 6141 | first diffractive |
| 6142 | second diffractive structure |
| 6151 | first propagation path |
| 6152 | second propagation path |
| 6161 | peak wavelength sub-pupil |
| 6162 | secondary wavelength sub-pupil |
| 6163 | tertiary wavelength sub-pupil |
| 7000 | display device |
| 7100 | frame |
| 7200 | display structure |
| 7210 | waveguide |
| 7221 | in-coupling structure |
| 7223 | out-coupling structure |
| 7230 | optical engine |
| 7231 | first light source |
| 7232 | superluminescent light source |
| 8000 | vehicle |
| 8100 | display device |
| 8121 | in-coupling structure |
| 8122 | intermediate pupil expansion structure |
| 8123 | out-coupling structure |
| 8130 | optical engine |
| 8200 | window |

1. An optical engine for a display device,
the optical engine comprising an illumination arrangement comprising:
a first light source configured to emit first light having a first peak wavelength, λ1 peak, and
a superluminescent light source configured to emit second light having a second peak wavelength, λ2 peak different from the first peak wavelength, λ1 peak;
wherein the first light source is implemented as a laser light source or as a light emitting-diode source and the superluminescent light source comprises a superluminescent diode.

2. An optical engine according to claim 1, wherein the second peak wavelength, λ2 peak, is higher than the first peak wavelength, λ1 peak.

3. An optical engine according to claim 1, wherein the second light has a second optical spectrum with a full-widthhalf-maximum, FWHM, linewidth, Δλ2 FWHM greater than or equal to 2 nm, or to 3 nm, or to 4 nm, or to 5 nm and/or less than or equal to 50 nm, or to 40 nm, or to 30 nm, or to 20 nm, or to 10 nm.

4. An optical engine according to claim 1, wherein the second peak wavelength, λ2 peak, lies in a red wavelength range extending from 600 nm to 750 nm, or from 610 nm to 700 nm, or from 620 nm to 650 nm, or from 625 nm to 640 nm.

5. An optical engine according to claim 1, wherein the superluminescent diode comprises an active layer comprising aluminum gallium indium phosphide, AlGaInP.

6. An optical engine according to claim 1, wherein the illumination arrangement comprises a further light source configured to emit third light having a third peak wavelength, λ3 peak, different from each of the first peak wavelength, λ1 peak, and the second peak wavelength, λ2 peak.

7. An optical engine according to claim 6, wherein the further light source is implemented as a further laser light source or as a further superluminescent light source.

8. An optical engine according to claim 6, wherein the second peak wavelength, λ2 peak, is higher than the third peak wavelength, λ3 peak.

9. An optical engine according to claim 1, wherein the optical engine further comprises a light scanner arrangement for deflecting light generated by the illumination arrangement.

10. An optical engine according to claim 1, wherein the light scanner arrangement comprises a micromirror scanner.

11. A display structure, comprising:
a waveguide,
an in-coupling structure, and
an optical engine in accordance with claim 1 configured to direct
light via the in-coupling structure into the waveguide for propagation in the waveguide by total internal reflection.

12. A display structure according to claim 11, wherein the incoupling structure is implemented as a diffractive in-coupling structure.

13. A display structure according to claim 11, wherein the waveguide has a thickness, T, greater than or equal to 0.25 mm, or to 0.27 mm, or to 0.3 mm and/or less than or equal to 5 mm, or to 2 mm, or to 1 mm.

14. A display device comprising a display structure in accordance with any of claim 11.

15. A display device according to claim 14 implemented as a see-through display device, such as a head-up display device.

16. A display device according to claim 14 implemented as a head-mounted display device.

17. A vehicle comprising a display device in accordance with claim 14.
